(19) United States
(12) Patent Application Publication
(10) Pub. No.: US 2024/0176587 A1
(43) Pub. Date: May 30, 2024

(54) MULTI-BIT ANALOG MULTIPLICATION AND ACCUMULATION CIRCUIT SYSTEM

(71) Applicant: NATIONAL YANG MING CHIAO TUNG UNIVERSITY, Hsinchu City (TW)

(72) Inventors: Shyh-Jye JOU, Hsinchu County (TW); Tuo-Hung HOU, Hsinchu City (TW); Tian-Sheuan CHANG, Hsinchu City (TW); Kuan-Chih LIN, Taipei City (TW); Hao ZUO, Tainan City (TW)

(21) Appl. No.: 18/340,643

(22) Filed: Jun. 23, 2023

(30) Foreign Application Priority Data
Nov. 30, 2022 (TW) 111146007

(51) Int. Cl. G06F 7/544; G06F 7/50; G06F 7/523; H03M 1/46

(52) U.S. Cl. CPC G06F 7/5443; G06F 7/50; G06F 7/523; H03M 1/466

(57) ABSTRACT

A multi-bit analog multiplication and accumulation circuit system, which includes: a plurality of analog multiplication circuits, first to fourth accumulation lines, and a binary place value combiner. Each of the analog multiplication circuits performs multiplications on four-bit input data and four-bit weight data, wherein each of the analog multiplication circuits includes four capacitor and switch arrays for performing multiplications on one bit of the four-bit input data and the four-bit weight data. Each of the accumulation lines outputs an accumulation of multiplications performed by each capacitor switch array of each analog multiplication circuit on one bit of the four-bit input data and the four-bit weight data. The binary place value combiner sums up the accumulated result outputted from the accumulation line with corresponding binary place value.

### BACKGROUND

### Field of Disclosure

The present disclosure relates to a circuit system and, more particularly, to a multi-bit analog multiplication and accumulation circuit system.

### Description of Related Art

With the development of artificial intelligence (AI), a neural network with good quality is required. Neural networks have to perform a large number of multiply accumulate (MAC) operations, while prior processors often cannot meet the requirements of low energy consumption and low computing delay when executing AI-related applications. Therefore, computing in memory (CIM) technology was developed to overcome the bottleneck of the prior processor. In order to implement complicated AI-related applications, current processors in the market must consume a lot of power and time, and their internal components are expensive and occupy a large area. Moreover, most of the current processors perform operations in the form of digital signal processing, which often produces errors. In other words, the current technology still needs to be improved.

Therefore, it is desired to provide an improved circuit system to mitigate and/or obviate the existing defects.

### SUMMARY

The present disclosure provides a multi-bit analog multiplication and accumulation circuit system, which can perform a multiplication and accumulation operation on a plurality of four-bit input data and four-bit weight data during one CIM period, thereby saving a lot of power and circuit area, improving the accuracy of MAC operation, or achieving lower computational delays.

The multi-bit analog multiplication and accumulation circuit system is provided for performing a multiplication and accumulation operation on a plurality of four-bit input data and four-bit weight data during one CIM period, and includes: a plurality of analog multiplication circuits for respectively performing multiplications on four-bit input data and four-bit weight data, respectively, wherein each analog multiplication circuit includes four capacitor switch arrays, each performing multiplications on one bit of the four-bit input data and the four-bit weight data; a first accumulation line, a second accumulation line, a third accumulation line and a fourth accumulation line, wherein each accumulation line outputs an accumulation of multiplications performed by each capacitor switch array of each analog multiplication circuit on one bit of the four-bit input data and the four-bit weight data; and a binary place value combiner electrically connected to the first accumulation line, the second accumulation line, the third accumulation line and the fourth accumulation line for summing up accumulated results outputted by each accumulation line with corresponding binary place value, so as to output a final multiplication and accumulation result of the CIM period.

Other novel features of the disclosure will become more apparent from the following detailed description when taken in conjunction with the accompanying drawings.

### BRIEF DESCRIPTION OF DRAWINGS

FIG. 1 is a system architecture diagram of the multi-bit analog multiplication and accumulation circuit system according to a first embodiment of the present disclosure.

FIG. 2A is a detailed circuit diagram of a single analog multiplication circuit according to an embodiment of the present disclosure.

FIG. 2B is a schematic diagram of a basic voltage and a first predetermined value according to an embodiment of the present disclosure.

FIG. 3 is a detailed circuit diagram of a binary place value combiner according to an embodiment of the present disclosure.

FIG. 4 is a schematic diagram of a multiplication and accumulation operation process according to an embodiment of the present disclosure.

FIG. 5 is a schematic diagram of an analog to digital conversion module according to an embodiment of the present disclosure.

FIG. 6 is a schematic diagram of a basic voltage and a second predetermined value according to an embodiment of the present disclosure.

### DETAILED DESCRIPTION OF EMBODIMENT

The implementation of the present disclosure is illustrated by specific embodiments to enable persons skilled in the art to easily understand the other advantages and effects of the present disclosure by referring to the disclosure contained therein. The present disclosure is implemented or applied by other different, specific embodiments. Various modifications and changes can be made in accordance with different viewpoints and applications to details disclosed herein without departing from the spirit of the present disclosure.

The implementation of the present disclosure is illustrated by specific embodiments to enable persons skilled in the art to easily understand the other advantages and effects of the present disclosure by referring to the disclosure contained therein. The present disclosure is implemented or applied by other different, specific embodiments. Various modifications and changes can be made in accordance with different viewpoints and applications to details disclosed herein without departing from the spirit of the present disclosure.

In addition, the description of “when . . . ” or “while . . . ” in the present disclosure means “now, before, or after”, etc., and is not limited to occurrence at the same time. In the present disclosure, the similar description of “disposed on” or the like refers to the corresponding positional relationship between the two elements, and does not limit whether there is contact between the two elements, unless specifically limited. Furthermore, when the present disclosure recites multiple effects, if the word “or” is used between the effects, it means that the effects can exist independently, but it does not exclude that multiple effects can exist at the same time.

In addition, the terms “connect” or “couple” in the description and claims not only refer to direct connection with another component, but also refer to indirect connection or electrical connection with another component. In addition, electrical connection includes direct connection, indirect connection, or communication between two components by radio signals.

In addition, in the specification and claims, the terms “almost”, “about”, “approximately” or “substantially” usually means within 10%, 5%, 3%, 2%, 1% or 0.5% of a given value or range. The quantity given here is an approximate quantity; that is, without specifying “almost”, “about”, “approximately” or “substantially”, it can still imply the meaning of “almost”, “about”, “approximately” or “substantially”. In addition, the term “range of the first value to the second value” or “range between the first value and the second value” indicates that the range includes the first value, the second value, and other values in between.

In addition, each component may be implemented as a single circuit or an integrated circuit in a suitable manner, and may include one or more active components, such as transistors or logic gates, or one or more passive components, for example, resistors, capacitors, or inductors, but not limited thereto. The components may be connected to each other in a suitable manner, for example, respectively matching the input signal and the output signal, and using one or more lines to form a series connection or a parallel connection. In addition, each component may allow input and output signals to enter and exit sequentially or in parallel. The aforementioned configurations are determined according to the actual application.

In addition, in the preset disclosure, terms such as “system”, “apparatus”, “device”, “module”, or “unit” may refer to an electronic component or a digital circuit composed of multiple electronic components, an analog circuit, or other circuits in a broader sense, and unless otherwise specified, they do not necessarily have a hierarchical relationship.

In addition, the technical features of different embodiments disclosed in the present disclosure may be combined to form another embodiment.

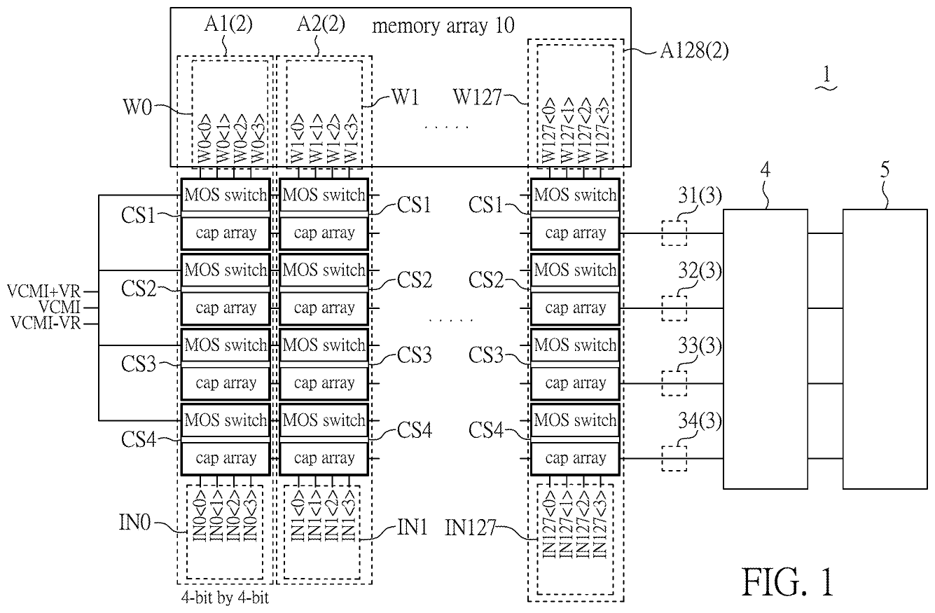

FIG. 1 is a system architecture diagram of a multi-bit analog multiplication and accumulation circuit system 1 according to the first embodiment of the present disclosure. The multi-bit analog multiplication and accumulation circuit system 1 can perform a multiplication and accumulation operation on a plurality of four-bit input data and four-bit weight data during one CIM period. As shown in FIG. 1, the multi-bit analog multiplication and accumulation circuit system 1 may include a plurality of analog multiplication circuits 2, a plurality of accumulation lines 3, a binary place value combiner 4 and an analog to digital conversion (ADC) module 5. The analog multiplication circuits 2 are respectively electrically connected to a memory array 10, wherein the memory array 10 stores a plurality of four-bit weight data (such as W0˜W127). In addition, the group of analog multiplication circuits 2 may receive a plurality of four-bit input data (such as IN0˜IN127) from the outside.

Each analog multiplication circuit 2 performs multiplications on a set of four-bit input data and a set of four-bit weight data, such as IN0×W0, IN1×W1, . . . , IN127×W127, and so on. In addition, each analog multiplication circuit 2 may include four capacitor switch arrays CS1˜CS4, and each capacitor switch array CS1˜CS4 performs multiplication on one bit of the four-bit input data and the four-bit weight data. For example, the first capacitor switch array CS1 of each analog multiplication circuit 2 may perform the multiplications on the first bit of the four-bit input data and the four-bit weight data, such as IN0<0>×W0, IN1<0>×W1, . . . , IN127<0>×W127, etc., and so on for the operation of other capacitor switch arrays. The multiplication result outputted by the analog multiplication circuit 2 is an analog signal.

The multiplication results of the capacitor switch arrays CS1˜CS4 of the analog multiplication circuits 2 will be accumulated on the accumulation lines 3, and outputted to the binary place value combiner 4 through the accumulation lines 3, respectively. For example, the results of the multiplications performed by the first capacitor switch array CS1 of the analog multiplication circuits 2 will be accumulated on one of the accumulation lines 3 and outputted (for example, IN0<0>×W0+IN1<0>×W1+ . . . +IN127<0>×W127), and so on. It is noted that the accumulation results outputted by the accumulation lines 3 may be analog signals.

The binary place value combiner 4 is electrically connected to the accumulation lines 3, respectively, and is used to sum up the accumulated results outputted by each accumulation line 3 with the corresponding binary place value, so as to output the final multiplication and accumulation result of one CIM. It is noted that the final multiplication and accumulation result is an analog signal.

The analog to digital conversion module 5 may convert the final multiplication and accumulation result from an analog signal form to a digital signal.

As a result, the multi-bit analog multiplication and accumulation circuit system 1 may perform a multiplication and accumulation operation on a plurality of four-bit input data and four-bit weight data within one CIM period. Next, the above elements will be described in more detail.

In one embodiment, the memory array 10 may be, for example, a resistive random access memory (RRAM) array, but it is not limited thereto, while other types of memory arrays may also be used in the present disclosure.

In one embodiment, the analog multiplication circuits 2 may, for example, include 128 analog multiplication circuits (denoted as A1˜A128), and the accumulation lines 3 may include first accumulation line 31 to fourth accumulation line 34. Furthermore, the first capacitor switch arrays CS1 of the analog multiplication circuits 2 may be all connected to the first accumulation line 31, the second capacitor switch arrays CS2 of the analog multiplication circuits 2 may be all connected to the second accumulation line 32, the third capacitor switch arrays CS3 of the analog multiplication circuits 2 may be all connected to the third accumulation line 33, and the fourth capacitor switch array CS4 of the analog multiplication circuits 2 may be all connected to the fourth accumulation line 34. The numbers of the analog multiplication circuits 2 and accumulation lines 3 are for illustrative purpose only, while the present disclosure is not limited thereto.

During one CIM period, the memory array 10 may input 128 sets of four-bit weight data to the analog multiplication circuits A1-A128, respectively, and each of the analog multiplication circuits A1-A128 also receives a four-bit input data from the outside at the same time. Therefore, during this CIM period, the analog multiplication circuits A1˜A128 may perform multiplications on 128 four-bit input data and four-bit weight data in total.

Furthermore, in one embodiment, the four-bit input data received by the analog multiplication circuits A1˜A128 from the outside may be the same set of four-bit input data, so that the multiplication performed by each analog multiplication circuit A1˜A128 may be regarded as the multiplication performed on the same set of four-bit input data and 128 sets of four-bit weight data. In another embodiment, the four-bit input data received by the analog multiplication circuits A1˜A128 from the outside may be different four-bit input data, wherein the first set of four-bit input data will be multiplied by the first set of four-bit weight data, the second set of four-bit input data will be multiplied by the second set of four-bit weight data, and so on. Accordingly, the set of the analog multiplication circuits 2 may perform a total of 128 multiplications during the CIM period, and the 128 multiplications may be performed synchronously. However, the present disclosure is not limited thereto.

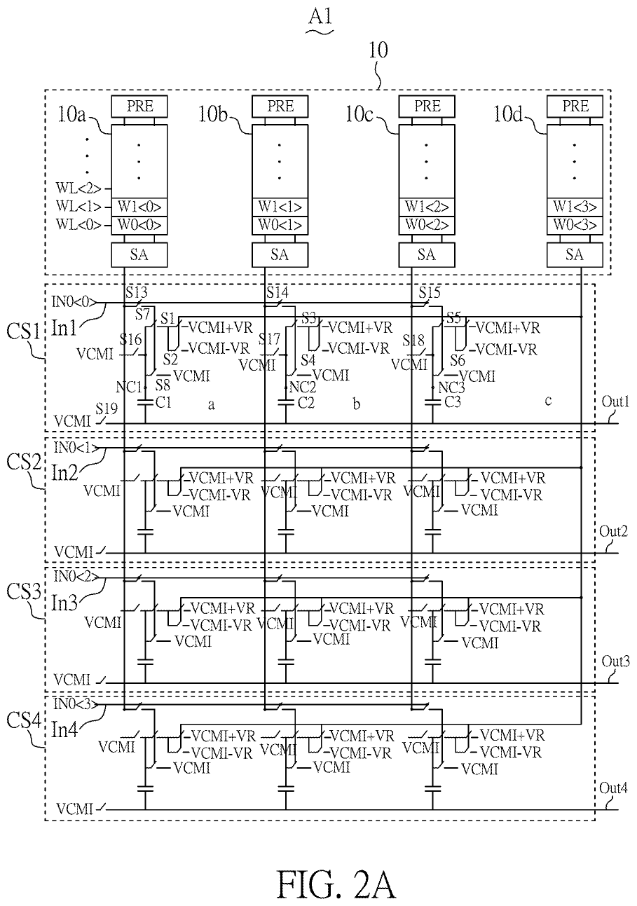

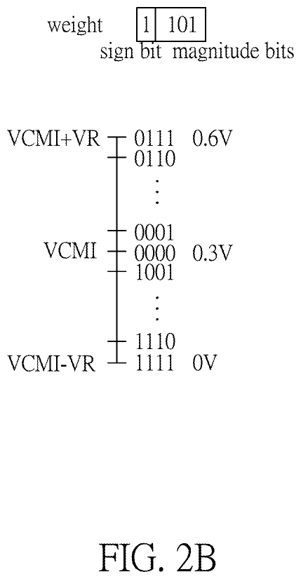

Next, the details of the “analog multiplication circuits A1˜A128” will be described. FIG. 2A is a detailed circuit diagram of a single analog multiplication circuit according to an embodiment of the present disclosure, and please also refer to FIG. 1 for reference. In FIG. 2A, the first analog multiplication circuit A1 is taken as an example, and the details of other analog multiplication circuits can be known accordingly.

As shown in FIG. 2A, the analog multiplication circuit A1 includes four capacitor switch arrays CS1˜CS4, wherein the capacitor switch arrays CS1˜CS4 have the same circuit structure and thus, in the following, only the capacitor switch array CS1 is described while the details of the capacitor switch arrays CS2˜CS4 can be known by analogy.

The analog multiplication circuit A1 may be electrically connected with four memory units 10a˜10d of the memory array 10. During one CIM period, the memory units 10a˜10d are responsible for providing a set of four˜bit weight data to the first analog multiplication circuit A1, wherein the memory units 10a˜10c respectively provide three amplitude bits of the set of four-bit weight data, the memory unit 10d may provide the sign magnitude of the set of four-bit weight data. The sign bit may represent the most significant bit (MSB) of the set of four-bit weight data. In addition, the memory unit 10a may provide the least significant bit (LSB) of the set of four-bit weight data.

The first capacitor switch array CS1 includes first capacitor C1 to third capacitor C3, a plurality of switches S1˜S19, an input line In1 and an output line Out1. Similarly, the second capacitor switch array CS2 includes three capacitors, nineteen switches, an input line In2 and an output line Out2. The third capacitor switch array CS3 includes three capacitors, nineteen switches, an input line In3 and an output line Out3. The fourth capacitor switch array CS4 includes three capacitors, nineteen switches, an input line In4 and an output line Out4.

In addition, the first capacitor switch array CS1 may be divided into three sub-sections, which are respectively represented by sub-section “a”, sub-section “b” and sub-section “c”. In addition, in one embodiment, the switches S1˜S19 may be MOSFETs, each having a first end, a second end and a control end, but it is not limited thereto. Moreover, for the convenience of explanation, the left side of the switches S1˜S19 in the figure will be named as the first end (such as the drain or source), the right side in the figure will be named as the second end (such as the source or drain), and the to-be-controlled end of the switch S1˜S19 is named as the control end (such as the gate).

The sub-section “a” may include a first capacitor C1 and switches S1, S2, S7, S8, S13 and S16. In one embodiment, one end of the first capacitor C1 is electrically connected to the first end of the switch S8, and the other end of the first capacitor C1 is electrically connected to the output line Out1. The first end of the switch S1 is electrically connected to the second end of the switch S7, the second end of the switch S1 is electrically connected to a basic voltage plus a first predetermined value (VCMI+VR), and the control end of the switch S1 is electrically connected to the memory unit 10d of the memory array 10. The first end of the switch S2 is electrically connected to the second end of the switch S7, the second end of the switch S2 is electrically connected to a basic voltage minus the first predetermined value (VCMI-VR), and the control end of the switch S2 is electrically connected to the memory unit 10d of the memory array 10. The first end of the switch S7 is electrically connected to the second end of the switch S16, and the control end of the switch S7 is electrically connected to the second end of the switch S13. The first end of the switch S8 is electrically connected to the second end of the switch S16, the second end of the switch S8 is electrically connected to a basic voltage VCMI, and the control end of the switch S8 is electrically connected to the second end of the switch S13. The first end of the switch S13 is electrically connected to the memory unit 10a of the memory array 10, and the control end of the switch S13 is electrically connected to the input line In1. The first end of the switch S16 is electrically connected to the basic voltage VCMI, and the control end of the switch S16 can be controlled by an external voltage (outputted from, for example but not limited to, an external controller).

The sub-section “b” may include a second capacitor C2 and switches S3, S4, S9, S10, S14 and S17. In one embodiment, one end of the second capacitor C2 is electrically connected to the first end of the switch S10, and the other end of the second capacitor C2 is electrically connected to the output line Out1. The first end of the switch S3 is electrically connected to the second end of the switch S9, the second end of the switch S3 is electrically connected to the basic voltage plus the first predetermined value (VCMI+VR), and the control end of the switch S3 is electrically connected to the memory unit 10d. The first end of the switch S4 is electrically connected to the second end of the switch S9, the second end of the switch S4 is electrically connected to the basic voltage minus the first predetermined value (VCMI-VR), and the control end of the switch S4 is electrically connected to the memory unit 10d. The first end of the switch S9 is electrically connected to the second end of the switch S17, and the control end of the switch S9 is electrically connected to the second end of the switch S14. The first end of the switch S10 is electrically connected to the second end of the switch S17, the second end of the switch S10 is electrically connected to the basic voltage VCMI, and the control end of the switch S10 is electrically connected to the second end of the switch S14. The first end of the switch S14 is electrically connected to the memory unit 10b, and the control end of the switch S14 is electrically connected to the input line In1. The first end of the switch S17 is electrically connected to the basic voltage VCMI, and the control end of the switch S17 may be controlled by an external voltage.

The sub-section “c” may include a third capacitor C3 and switches S5, S6, S11, S12, S15 and S18. In one embodiment, one end of the third capacitor C3 is electrically connected to the first end of the switch S12, and the other end of the third capacitor C3 is electrically connected to the output line Out1. The first end of the switch S5 is electrically connected to the second end of the switch S11, the second end of the switch S5 is electrically connected to the basic voltage plus the first predetermined value (VCMI+VR), and the control end of the switch S5 is electrically connected to the memory unit 10d. The first end of the switch S6 is electrically connected to the second end of the switch S11, the second end of the switch S6 is electrically connected to the basic voltage minus the first predetermined value (i.e., VCMI-VR), and the control end of the switch S6 is electrically connected to the memory unit 10d. The first end of the switch S11 is electrically connected to the second end of the switch S18, and the control end of the switch S11 is electrically connected to the second end of the switch S15. The first end of the switch S12 is electrically connected to the second end of the switch S18, the second end of the switch S12 is electrically connected to the basic voltage VCMI, and the control end of the switch S12 is electrically connected to the second end of the switch S15. The first end of the switch S15 is electrically connected to the memory unit 10c, and the control end of the switch S15 is electrically connected to the input line In1. The first end of the switch S18 is electrically connected to the basic voltage VCMI, and the control end of the switch S18 may be controlled by an external voltage.

In addition, the first end of the switch S19 is electrically connected to the basic voltage VCMI, the second end of the switch S19 is electrically connected to the output line Out1, and the control end of the switch S19 may be controlled by an external voltage.

Furthermore, the second capacitor switch array CS2, the third capacitor switch array CS3 and the fourth capacitor switch array CS4 may have a circuit structure similar to that of the first capacitor switch array CS1, so that the circuit structures of the second capacitor switch array CS2, the third capacitor switch array CS3 and the fourth capacitor switch array CS4 may be known to those skilled in the art based on the first capacitor switch array CS1 and FIG. 2A, and thus a detailed description is deemed unnecessary.

Next, the operation of the first capacitor switch array CS1 will be described. Before the multiplication starts, the switches S16-S19 are turned on, and the voltage on the output line Out1 and the other ends of the capacitors C1˜C3 are reset to be the basic voltage VCMI.

When starting the multiplication, the switch S19 is turned off, and the voltage on the output line Out1 becomes a floating state, while the ends of the first capacitor C1, the second capacitor C2 and the third capacitor C3 that are connected to the output line Out1 also become a floating state. At this moment, if the voltage at the other end of the first capacitor C1, the second capacitor C2 or the third capacitor C3 changes, the voltage difference will be coupled to the output line Out1.

In addition, when starting the multiplication, the four bits of the four-bit weight data stored in the memory units 10a-10d are respectively read by a sensor amplifier (SA) and sent to the first capacitor switch array CS1. At the same time, one bit of the four-bit input data is inputted to the control ends of the switches S13, S14 and S15 through the input line In1. When the value of the bit of the four-bit input data is 1, the multiplication result of the bit and the four-bit weight data is the four-bit weight data itself, so that the switches S13, S14 and S15 are turned on, and the amplitude bit of the four-bit weight data may actually enter the inside of the first capacitor switch array CS1 through the switches S13, S14 and S15. On the contrary, when the value of the bit of the four-bit input data is 0, the multiplication result of the bit and the four-bit weight data will be “0000”, so that switches S13, S14 and S15 are turned off.

In addition, the switches S1, S2, S3, S4, S5 and S6 may be controlled by the sign bit of the four-bit weight data. When the sign bit is 0, it indicates that the weight data is positive, while the switches S1, S3 and S5 are configured to be turned on and the switches S2, S4 and S6 are configured to be turned off. At this moment, the other end of the first capacitor C1 may be electrically connected to VCMI+VR through the switch S7, or electrically connected to VCMI through the switch S8, and the other end of the second capacitor C2 may be electrically connected to VCMI+VR through the switch S9, or electrically connected to VCMI through the switch S10, while the other end of the third capacitor C3 may be electrically connected to VCMI+VR through the switch S11, or electrically connected to VCMI through the switch S12. On the contrary, when the sign bit is 1, it indicates that the weight data is negative, and the switches S1, S3 and S5 are configured to be turned off and the switches S2, S4 and S6 are configured to be turned on. Therefore, the other end of the first capacitor C1 may be electrically connected to VCMI-VR through the switch S7, or electrically connected to VCMI through switch S8, and the other end of the second capacitor C2 may be electrically connected to VCMI-VR through switch S9, or electrically connected to VCMI through switch S10, while the other end of the third capacitor C3 may be electrically connected to VCMI-VR through the switch S11, or electrically connected to VCMI through the switch S12.

The basic voltage VCMI will be described first. FIG. 2B is a schematic diagram of the basic voltage and the first predetermined value according to an embodiment of the present disclosure. As shown in FIG. 2B, the basic voltage VCMI may correspond to digital signal of “0000”. In one embodiment, the basic voltage VCMI corresponds to analog voltage of 0.3V. In one embodiment, the basic voltage VCMI to the basic voltage plus the first predetermined value VCMI+VR may correspond to digital signal of “0000” to “0111” and correspond to analog voltage of 0.3V to 0.6V. In one embodiment, the basic voltage minus the first predetermined value VCMI-VR to the basic voltage VCMI may correspond to digital signal of “1111” to “0000” and correspond to analog voltage of 0V to 0.3V. The aforementioned numerical values are only examples but not limitations. As a result, the basic voltage and the first predetermined value can be understood.

Please refer to FIG. 2A again. The least significant bit (LSB) of the amplitude bits of the four-bit weight data may control the on or off of the switches S7 and S8. When the least significant bit is 1, the switch S7 is turned on, and the switch S8 is turned off. At this moment, the node NC1 connected to the first capacitor C1 may generate a voltage difference plus a predetermined value (ΔV+VR), and ΔV+VR may be coupled to the output line Out1 through the first capacitor C1. On the contrary, when the least significant bit is 0, the switch S7 is turned off, and the switch S8 is turned on, while there is no voltage difference generated at the node NC1.

Similarly, the second amplitude bit of the four-bit weight data may control the on or off of the switches S9 and S10. When the second amplitude bit is 1, the switch S9 is turned on, and the switch S10 is turned off. At this moment, the node NC2 connected to the second capacitor C2 may generate ΔV+VR, and ΔV+VR may be coupled to output line Out1 through the second capacitor C2. On the contrary, the switch S9 is turned off, and the switch S10 is turned on, while there is no voltage difference generated at the node NC2.

Similarly, the third amplitude bit of the four-bit weight data may control the on or off of the switches S11 and S12. When the third amplitude bit is 1, the switch S11 is turned on, and the switch S12 is turned off. At this moment, the node NC3 connected to the third capacitor C3 may generate ΔV+VR, and ΔV+VR may be coupled to output line Out1 through the third capacitor C3. On the contrary, the switch S11 is turned off, and the switch S12 is turned on, while there is no voltage difference generated at the node NC3.

In addition, the ratio of the capacitance values of the first capacitor C1, the second capacitor C2 and the third capacitor C3 may be configured to be 1:2:4 to represent the place value of the weight data.

Thus, after the multiplication, the sum of the voltage differences on the output line Out1 connected to the first capacitor switch array CS1 of the analog multiplication circuit A1 may be expressed as equation (1):

$$Δ {V}_{Out 1} = \frac{{C}_{1} Δ {V}_{1} + {C}_{2} Δ {V}_{2} + {C}_{3} Δ {V}_{3}}{{C}_{total}} ; \qquad equation ( 1 )$$

wherein ΔVₒᵤₜ₁ is the sum of the voltage differences on the output line Out1 of the analog multiplication circuit A1, which may also represent part of the multiplication result of the analog multiplication circuit A1, C₁ is the capacitance value of the first capacitor C1, C₂ is the capacitance value of the second capacitor C2, C₃ is the capacitance value of the third capacitor C1, ΔV₁ is the voltage difference of the node NC1 coupled to the output line Out1, ΔV₂ is the voltage difference of the node NC2 coupled to the output line Out1, ΔV₃ is the voltage difference of the node NC2 coupled to the output line Out1.

Similarly, when starting the multiplication, the four-bit weight data is also inputted to the second capacitor switch array CS2, the third capacitor switch array CS3 and the fourth capacitor switch array CS4, and the other bits of the four-bit input data are also inputted to the second capacitor switch array CS2, the third capacitor switch array CS3 and the fourth capacitor switch array CS4 through the input lines In2˜In4, respectively, wherein the multiplication performed by the second capacitor switch array CS2, the third capacitor switch array CS3 and the fourth capacitor switch array CS4 can be known by referring to the description of the first capacitor switch array CS1, and the voltage differences on the output line Out2 of the second capacitor switch array CS2, the output line Out3 of the third capacitor switch array CS3 and the output line Out4 of the fourth capacitor switch array CS4 can also be derived from equation (1).

Furthermore, the multiplication performed by each analog multiplication circuit A1˜A128 may be known by referring to the description of the aforementioned analog multiplication circuit A1, and part of the multiplication results of the first capacitor switch array CS1 to fourth capacitor switch array CS4 is outputted through respective output lines Out1˜Out4.

With the analog multiplication circuits A1˜A128, the architecture uses MOS transistor switches and capacitors, which will not generate large DC current during operation (for example, the current is only between 0V and 0.6V), so that the power consumption can be reduced. In addition, because the switches and capacitors are electronic components with small size, the occupied area of the components can be reduced. Besides, by using analog multiplication, the parallelism of computing can be increased. As a result, the analog multiplication circuits A1˜A128 can be understood.

Next, the details of “the first accumulation line 31 to the fourth accumulation line 34” will be described, and please refer to FIG. 1 and FIG. 2A again.

As shown in FIG. 1 and FIG. 2A, the output lines Out1 of the first capacitor switch arrays CS1 of the analog multiplication circuits A1˜A128 may be connected in series to form the first accumulation line 31. Through the serial connection of the output lines Out1, the multiplication results outputted by the first capacitor switch arrays CS1 of the analog multiplication circuits A1˜A128 may be accumulated on the first accumulation line 31; in other words, the first accumulation line 31 may output the accumulation of the multiplication results of the first bit of the four˜bit input data and all four˜bit weight data.

Similarly, the output lines Out2 of the second capacitor switch arrays CS2 of the analog multiplication circuits A1˜A128 may be connected in series to form the second accumulation line 32. Through the serial connection of the output lines Out2, the multiplication results outputted by the second capacitor switch arrays CS2 of the analog multiplication circuits A1˜A128 may be accumulated on the second accumulation line 32; in other words, the second accumulation line 32 may output the accumulation of the multiplication results of the second bit of the four˜bit input data and all four˜bit weight data may be output.

Similarly, the output lines Out3 of the third capacitor switch arrays CS3 of the analog multiplication circuits A1˜A128 may be connected in series to form the third accumulation line 33. Through the serial connection of the output lines Out3, the multiplication results outputted by the third capacitor switch arrays CS3 of the analog multiplication circuits A1˜A128 may be accumulated on the third accumulation line 33; in other words, the third accumulation line 33 may output the accumulation of the the multiplication results of the third bit of the four˜bit input data and all four˜bit weight data.

Similarly, the output lines Out4 of the fourth capacitor switch arrays CS4 of each analog multiplication circuit A1˜A128 can be connected in series to form the fourth accumulation line 34. Through the series connection of these output lines Out4, the multiplication results outputted by the fourth capacitor switch arrays SC4 of the analog multiplication circuits A1˜A128 may be accumulated on the fourth accumulation line 34; in other words, the fourth accumulation line 34 may output the accumulation of the multiplication results of the fourth bit of the four-bit input data and all four-bit weight data may be output.

In one embodiment, the accumulation of the multiplication results outputted by each accumulation line 31-34 may be expressed as equation (2.2):

$$Δ {V}_{accumulation line} = \frac{{C}_{M} Δ {V}_{1} + {C}_{M} Δ {V}_{2} + … + {C}_{M} Δ {V}_{128}}{128 \times {C}_{M}} {V}_{accumulation line} = VCMI + \frac{{C}_{M} Δ {V}_{1} + {C}_{M} Δ {V}_{2} + … + {C}_{M} Δ {V}_{128}}{128 \times {C}_{M}} ; \qquad equation ( 2.1 )$$

$$Δ {V}_{accumulation line} = \frac{{C}_{M} Δ {V}_{1} + {C}_{M} Δ {V}_{2} + … + {C}_{M} Δ {V}_{128}}{128 \times {C}_{M}} {V}_{accumulation line} = VCMI + \frac{{C}_{M} Δ {V}_{1} + {C}_{M} Δ {V}_{2} + … + {C}_{M} Δ {V}_{128}}{128 \times {C}_{M}} ; \qquad equation ( 2.2 )$$

where V_{accumulation line} is the actual output of each accumulation line, C_{M} is the total capacitance value of a capacitor switch array, ΔV_{1˜128} is the voltage difference outputted by one of the output lines of the capacitor switch arrays (for example, ΔV_{OUT1˜OUT128}).

As a result, instead of converting the multiplication result into a digital form before each accumulation, the architecture of the present disclosure continues to calculate in the form of an analog voltage, which not only reduces power consumption and the area occupied by the components due to not requiring an additional converter, but also ensures that there is no error value generated by analog to digital conversion in the operation process.

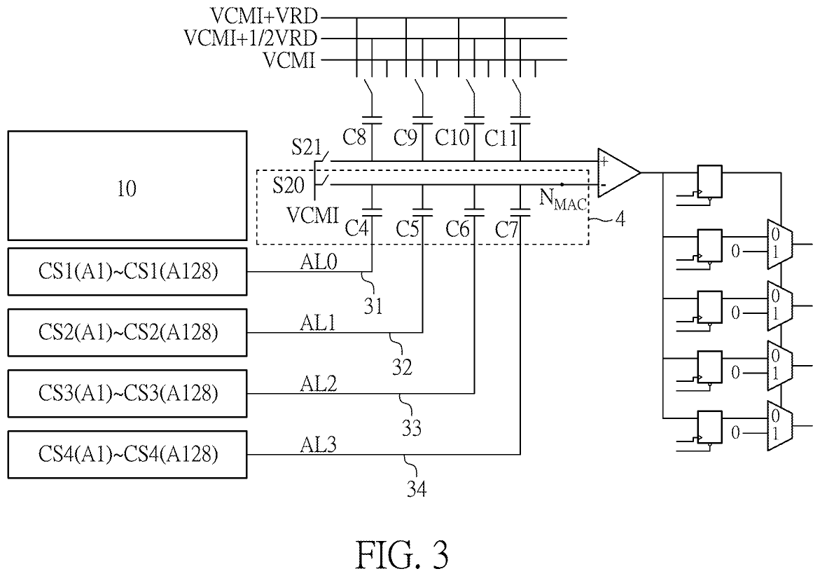

FIG. 3 is a detailed circuit diagram of the binary place value combiner 4 according to an embodiment of the present disclosure, and please refer to FIG. 1 and FIG. 2A for auxiliary reference.

As shown in FIG. 3, the binary place value combiner 4 may include a fourth capacitor C4, a fifth capacitor C5, a sixth capacitor C6, a seventh capacitor C7 and a place combination switch S20 (hereinafter referred to as switch S20).

One end of the fourth capacitor C4 is electrically connected to the first accumulation line 31, and the other end of the fourth capacitor C4 is electrically connected to the second end of the switch S20. One end of the fifth capacitor C5 is electrically connected to the second accumulation line 32, and the other end of the fifth capacitor C5 is electrically connected to the second end of the switch S20. One end of the sixth capacitor C6 is electrically connected to the third accumulation line 33, and the other end of the sixth capacitor C6 is electrically connected to the second end of the switch S20. One end of the seventh capacitor C7 is electrically connected to the fourth accumulation line 34, and the other end of the seventh capacitor C7 is electrically connected to the second end of the switch S20. In addition, the first end of the switch S20 is electrically connected to the basic voltage VCMI, and the control end of the switch S20 may be controlled by an external voltage. In addition, in one embodiment, the ratio of the capacitance values of the fourth capacitor C4, the fifth capacitor C5, the sixth capacitor C6 and the seventh capacitor C7 is 1:2:4:8.

Through the configuration of the fourth capacitor C4 to the seventh capacitor C7, when the accumulation results of the first accumulation line 31 to the fourth accumulation line 34 are transmitted to the binary place value combiner 4, the total value of the accumulation result of each accumulation line 31-34 corresponding to the binary place value, i.e. the final multiplication and accumulation result, may be generated on a node N_MAC, wherein the final multiplication and accumulation result may be expressed as equation (3):

$${V}_{MAC} = VCMI + \frac{\begin{matrix}{C}_{u} Δ {V}_{AL 1} + ( 2 \times {C}_{u} ) Δ {V}_{AL 2} + \\ ( 4 \times {C}_{u} ) Δ {V}_{AL 3} + ( 8 \times {C}_{u} ) Δ {V}_{AL 4}\end{matrix}}{15 \times {C}_{u}} ; \qquad equation ( 3 )$$

where V_{MAC} is the final multiplication and accumulation result of this multiplication and accumulation, Cᵤ is the unit capacitance value of the fourth capacitor C4 to the seventh capacitor C7, and ΔV_{AL1˜AL4} are respectively the outputs of the first accumulation line 31 to the fourth accumulation line 34.

In one embodiment, VMAC may be between 0V and 0.6V (that is, 0V≤VMAC≤0.6V). When VMAC is 0.3V (that is, VMAC=0.3V), the final multiplication and accumulation result is 0. When VMAC is less than 0.3V (that is, VMAC<0.3V), the final multiplication and accumulation result is a negative value. When VMAC is greater than 0.3V (that is, VMAC>0.3V), the final multiplication and accumulation result is a positive value

As a result, the present disclosure may realize highly parallel multiplication and accumulation operation with low power consumption and high operation speed.

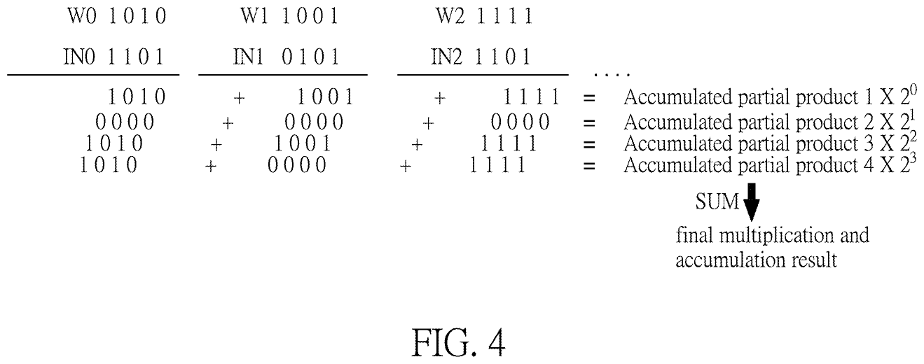

FIG. 4 is a schematic diagram of a multiplication and accumulation operation process according to an embodiment of the present disclosure, and please refer to FIGS. 1, 2 and 3 as auxiliary references at the same time. The embodiment in FIG. 4 takes the multiplication and accumulation operation of 3 weight data and 3 input data as an example, wherein the first weight data “1010” is multiplied by the first input data “1101”, the second weight data “1001” is multiplied by the second input data “0101”, the third weight data “1111” is multiplied by the third input data “1101”, and the aforementioned multiplication results are accumulated.

As shown in FIG. 4, through the analog multiplication circuits A1˜A128 and the accumulation lines 31-34 of the present disclosure, the LSB “1” of the first input data “1101” is multiplied by the first weight data “1010”, the LSB “1” of the second input data “1101” is multiplied by the second weight data “1001”, the LSB “1” of the third input data “1101” is multiplied by the third weight data “1111”, and then the three multiplication results “1010”, “1001” and “1111” are accumulated on the first accumulation line 31. Similarly, the second bit “0” of the first input data “1101” is multiplied by the first weight data “1010”, the second bit “0” of the second input data “1101” is multiplied by the second weight data “1001”, the second bit “0” of the third input data “1101” is multiplied by the third weight data “1111”, and then the three multiplication results “0000”, “0000” and “0000” are accumulated on the second accumulation line 32. By analogy, the three multiplication results “1010”, “1001” and “1111” are accumulated on the third accumulation line 33, and the three multiplication results “1010”, “0000” and “1111” are accumulated on the fourth accumulation line 34.

Afterwards, through the binary place value combiner of the present disclosure, the accumulation result of the first accumulation line 31 corresponds to a binary place value “2⁰”, the accumulation result of the second accumulation line 32 corresponds to a binary position value “2¹”, the accumulation result of the third accumulation line 33 corresponds to a binary place value “2²”, and the accumulation result of the fourth accumulation line 34 corresponds to a binary place value “2³”, which are then summed up to generate the final multiplication and accumulation result.

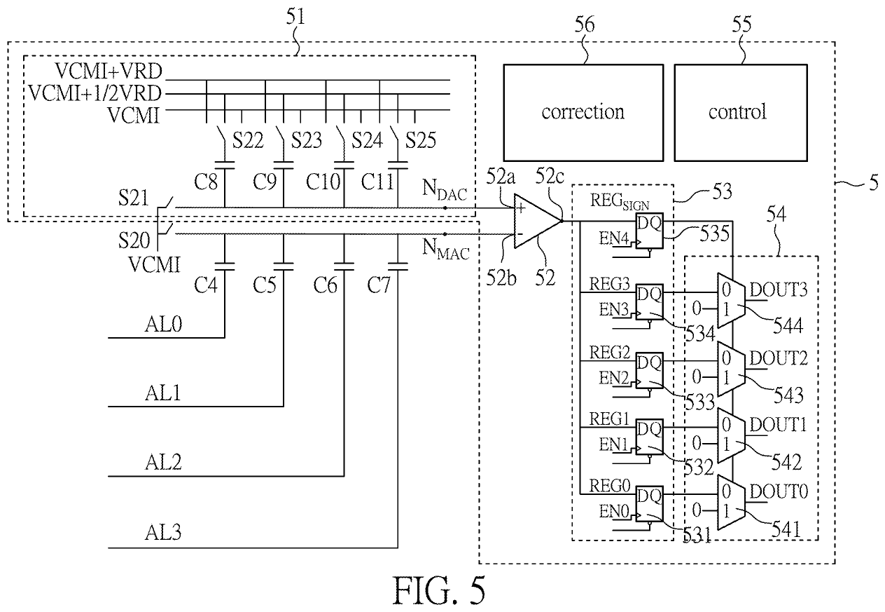

FIG. 5 is a schematic diagram of an analog to digital conversion module 5 according to an embodiment of the present disclosure, and please refer to FIGS. 1 to 4 at the same time. The analog to digital conversion module 5 may convert the total summed analog value from analog voltage signal to digital signal. In addition, the analog to digital conversion module 5 also has the function of a rectified linear unit (Relu), which may be used, for example, to activate neurons of neural networks.

As shown in FIG. 5, the analog to digital conversion module 5 may include a digital to analog converter 51, a comparator 52, a register group 53, a multiplexer group 54, a control circuit 55 and a correction circuit 56.

The digital to analog converter 51 may include four switch capacitors (hereinafter referred to as the eighth capacitor C8, the ninth capacitor C9, the tenth capacitor C10 and the eleventh capacitor C11), and switches S21-S25. One end of the eighth capacitor C8, one end of the ninth capacitor C9, one end of the tenth capacitor C10, and one end of the eleventh capacitor C11 are electrically connected to the second end of the switch S21, and are electrically connected to a node N_{DAC}. The other end of the eighth capacitor C8 is electrically connected to the first end of the switch S22, the other end of the ninth capacitor C9 is electrically connected to the first end of the switch S23, the other end of the tenth capacitor C10 is electrically connected to the first end of the switch S24, and the other end of the eleventh capacitor C11 is electrically connected to the first end of the switch S25. The first end of the switch S21 is electrically connected to the basic voltage VCMI. The second end of the switch S22, the second end of the switch S23, the second end of the switch S24 and the second end of the switch S25 are electrically connected to one of three predetermined voltages, wherein the three predetermined voltages are the basic voltage VCMI, the basic voltage plus half of the second variation value VCMI+0.5VRD, and the basic voltage plus the second variation value VCMI+VRD, respectively. In addition, whether the switches S21-S25 are switched on or not can be controlled by the control circuit 55. In addition, in one embodiment, the capacitance ratio of the eighth capacitor C8 to the eleventh capacitor C11 is 1:2:4:8, while it is not limited thereto.

The comparator 52 may have a first input end 52a, a second input end 52b and an output end 52c. The first input end 52a of the comparator 52 is electrically connected to the node N_{DAC}, the second input end 52b of the comparator 52 is electrically connected to the node N_{MAC}, and the output end 52c of the comparator 52 is electrically connected to the register group 53.

The register group 53 may include registers 531˜535. An input end D of each register 531˜535 is electrically connected to the output end 52c of the comparator 52, and each register 531˜535 has an enable end EN and an output end Q, wherein the enable end EN may be controlled by the control circuit 55, and the output end Q may be electrically connected to the multiplexer group 54.

The multiplexer group 54 may include multiplexers 541˜544. The input end (0) of the multiplexer 541 is electrically connected to the output end Q of the register 531. The input end (0) of the multiplexer 542 is electrically connected to the output end Q of the register 532. The input end (0) of the multiplexer 543 is electrically connected to the output end Q of the register 533 The input end (0) of the multiplexer 544 is electrically connected to the output end Q of the register 534. The input end (1) of each multiplexer 541˜544 is connected with a digital signal “0”. The multiplexers 541˜544 are activated by the output Q of the register 535.

In one embodiment, the correction circuit 56 is enabled to correct the input of the comparator 52 prior to the CIM operation. During the CIM operation, the switch S21 of the digital to analog converter 52 is first turned on, and the voltage V_{DAC} of the node N_{DAC} is reset to be the basic voltage VCMI.

When the binary place value combiner 4 inputs a stable voltage V_{MAC} to the second input end 52b of the comparator 52, the comparator 52 is enabled by the control circuit 55 to start to compare the voltage V_{DAC} of the node N_{DAC} with the voltage V_{MAC} of the node N_{MAC}, and store the comparison result in the register 535.

Furthermore, when the comparator 52 performs a comparison for the first time, the switch S21 is turned on, the switches S22-S25 are switched to be electrically connected to the basic voltage VCMI, and the voltage V_{DAC} of the node N_{DAC} is maintained at the basic voltage VCMI. At this moment, if V_{MAC} is greater than V_{DAC}, the comparator 52 outputs 0V, that is, outputs a digital signal “0”, which indicates that the result of this MAC is positive, and the fifth register 535 will control the multiplexers 541˜544 to output the data stored in the registers 531˜534. On the contrary, if V_{MAC} is less than or equal to V_{DAC}, the comparator 52 outputs 1.1V, that is, outputs a digital signal “1”, which indicates that the result of this MAC is negative, and the fifth register 535 controls the multiplexers 541˜544 to output a digital signal “0”. As a result, the function of a rectified linear unit (Relu) may be performed.

When the comparator 52 is about to perform the second comparison, the switch S21 is turned off, and the switches S22-S25 are switched to be electrically connected to the basic voltage plus half of the second predetermined value (VCMI+0.5VRD), so that the voltage V_{DAC} of the node N_{DAC} changes to VCMI+0.5VRD. After the comparator 52 compares V_{MAC} and V_{DAC} for the second time, the comparison result will be stored in the register 534, and the output of the register 534 not only is connected to the multiplexer 544, but also is connected to the switch S25, thereby switching the switch S25 so that the eleventh capacitor C11 is connected to a voltage source. The output Q of the register 534 represents the MSB of the four-bit multiplication and accumulation result. If the output of the register 534 is 0, that is, V_{MAC} is greater than V_{DAC}, the switch S25 is switched so that the eleventh capacitor C11 is electrically connected to the basic voltage plus the second predetermined value (VCMI+VRD). Therefore, V_{DAC} increases by (8/15)×(1/2)×VRD. On the other hand, if the output of the register 534 is 1, that is, V_{MAC} is less than or equal to V_{DAC}, the switch S25 is switched so that the eleventh capacitor C11 is connected to the basic voltage VCMI, thereby reducing V_{DAC} by (8/15)×(1/2)×VRD. In one embodiment, the variation of V_{DAC} may be expressed as equation (4):

$$Δ {V}_{DAC} = \frac{{C}_{8} Δ {V}_{C 8} + {C}_{9} Δ {V}_{C 9} + {C}_{10} Δ {V}_{C 10} + {C}_{11} Δ {V}_{C 11}}{{C}_{total}} ; \qquad equation ( 4 )$$

where ΔV_{DAC} is the variation of V_{DAC}, C₈ to C₁₁ are the capacitance values of capacitors C8 to C11, and ΔV_{C8} to ΔV_{C11} are the coupling voltage variations of capacitors C8˜C11, respectively.

Then, the comparator 52 performs a third comparison, and stores the comparison result in the register 533. The output Q of the register 533 represents the third bit of the four-bit multiplication and accumulation result, which is electrically connected to the multiplexer 543 and the switch S24, and controls the switch S24 to switch. When the output of the register 533 is 0, the switch S24 is switched so that the tenth capacitor C10 is electrically connected to VCMI+VRD thereby increasing V_{DAC} by (4/15)×(1/2)×VRD. On the contrary, when the output of the register 533 is 1, the switch S24 is switched so that the tenth capacitor C10 is electrically connect to VCMI, thereby reducing V_{DAC} by (4/15)×(1/2)×VRD.

Then, the comparator 52 performs a fourth comparison, and stores the comparison result in the register 532. The output Q of the register 532 represents the second bit of the four-bit multiplication and accumulation result, which is electrically connected to the multiplexer 542 and the switch S23, and controls the switch S23 to switch. When the output of the register 532 is 0, the switch S23 is switched so that the ninth capacitor C9 is electrically connected to VCMI+VRD, thereby increasing V_{DAC} by (2/15)×(1/2)×VRD. On the other hand, when the output of the register 532 is 1, the switch S23 is switched so that the ninth capacitor C9 is electrically connected to VCMI, thereby reducing V_{DAC} by (2/15)×(1/2)×VRD.

Then, the comparator 52 performs a fifth comparison, and stores the comparison result in the register 531. The output Q of the temporary register 531 represents the LSB of the four-bit multiplication and accumulation result, which is electrically connected to the multiplexer 541 and the switch S22, and controls the switch S22 to switch. When the output of the register 531 is 0, the switch S22 is switched so that the eighth capacitor C8 is electrically connected to VCMI+VRD, thereby increasing V_{DAC} by (1/15)×(1/2)×VRD. On the contrary, when the output of the register 531 is 1, the switch S22 is switched so that the eighth capacitor C8 is electrically connected to VCMI, thereby reducing V_{DAC} by (1/15)×(1/2)×VRD.

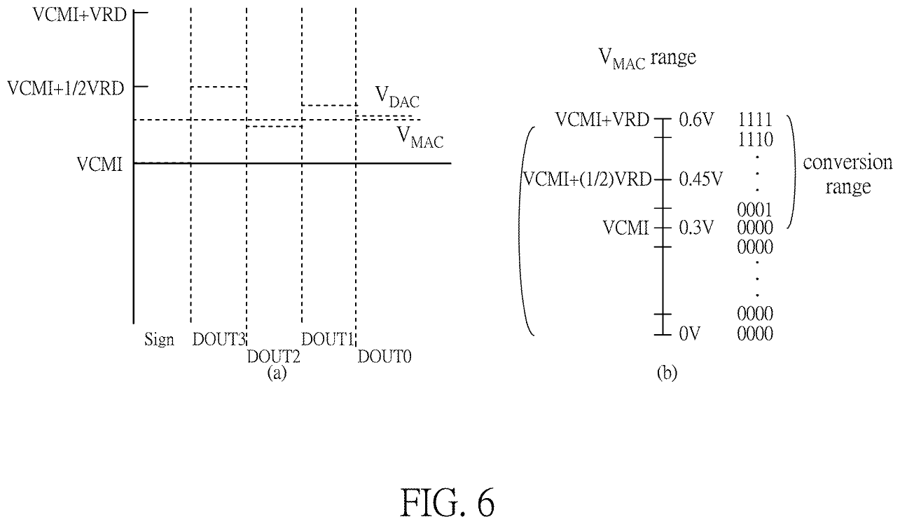

FIG. 6 is a schematic diagram of the basic voltage and the second predetermined value according to an embodiment of the present disclosure, and please refer to FIG. 1 to FIG. 5 at the same time. As shown in part (a) of FIG. 6, by successive comparisons between V_{DAC} and V_{MAC}, V_{DAC} gradually approaches V_{MAC}, and outputs one bit of the four-bit multiplication and accumulation result from MSB to LSB for each comparison. As shown in part (b) of FIG. 6, the basic voltage VCMI corresponds to the analog voltage 0.3V, and corresponds to the digital signal “0000”. In one embodiment, the basic voltage VCMI to the basic voltage plus the second predetermined value VCMI+VDR may correspond to analog voltage 0.3V to 0.6V and the digital signal “0000” to “1111”, and the basic voltage minus the second predetermined value VCMI-VDR to the basic voltage VCMI may correspond to the analog voltage 0V to 0.3V, and correspond to the digital signal “0000” to “0000”, that is, when the V_{MAC} is 0V to 0.3V, the analog to digital conversion module 5 will output digital signal “0000”. The aforementioned numerical values are only examples but not limitations.

As a result, the analog to digital conversion of the final multiplication and accumulation results can be completed, and the Relu process of the neural network can be realized at the same time.

Accordingly, the present disclosure provides a multi-bit analog multiplication and accumulation circuit system 1, which can provide low power consumption and high-speed CIM parallel multiplication and accumulation operation suitable for artificial intelligence. Alternatively, the multiplication and accumulation process of the present disclosure is performed in the form of analog signals, which can avoid errors caused by a large number of analog to digital conversions. Alternatively, the multiplication circuit of the present disclosure uses capacitors and switches without occupying a large component area.

In addition, as long as the features of the various embodiments of the present disclosure do not violate or conflict the spirit of the disclosure, they may be mixed and matched arbitrarily.

The aforementioned specific embodiments should be construed as merely illustrative, and not limiting the rest of the present disclosure in any way.

1. A multi-bit analog multiplication and accumulation circuit system for performing a multiplication and accumulation operation on a plurality of four-bit input data and four-bit weight data during one CIM period, including:
a plurality of analog multiplication circuits for respectively performing multiplications on four-bit input data and four-bit weight data, respectively, wherein each analog multiplication circuit includes four capacitor switch arrays, each performing multiplications on one bit of the four-bit input data and the four-bit weight data;
a first accumulation line, a second accumulation line, a third accumulation line and a fourth accumulation line, wherein each accumulation line outputs an accumulation of multiplications performed by each capacitor switch array of each analog multiplication circuit on one bit of the four-bit input data and the four-bit weight data; and
a binary place value combiner electrically connected to the first accumulation line, the second accumulation line, the third accumulation line and the fourth accumulation line for summing up accumulated results outputted by each accumulation line with corresponding binary place value, so as to output a final multiplication and accumulation result of the CIM period.

2. The multi-bit analog multiplication and accumulation circuit system as claimed in claim 1, wherein each capacitor array of each analog multiplication circuit includes three capacitors, a plurality of switches and an output line, in which a first end of each capacitor is electrically connected to part of the switches, a second end of each capacitor is electrically connected to the output line, one of the switches receives one of the weight data in the four-bit weight data, and whether one of the switches is turned on or not is controlled by one of magnitude bits of the four-bit input data.

3. The multi-bit analog multiplication and accumulation circuit system as claimed in claim 2, wherein each capacitor of each capacitor array corresponds to two of the switches, and the two switches corresponding to each capacitor are controlled by a sign magnitude in the four-bit weight data.

4. The multi-bit analog multiplication and accumulation circuit system as claimed in claim 3, wherein the first accumulation line is formed by connecting the output lines of the first capacitor arrays in the analog multiplication circuits in series, the second accumulation line is formed by connecting the output lines of the second capacitor arrays in the analog multiplication circuits in series, the third accumulation line is formed by connecting the output lines of the third capacitor arrays in the analog multiplication circuits in series, and the fourth accumulation line is formed by connecting the output lines of the fourth capacitor arrays in the analog multiplication circuits in series.

5. The multi-bit analog multiplication and accumulation circuit system as claimed in claim 4, wherein the binary place value combiner includes four capacitors, in which a first end of any one of the four capacitors is connected to an output node, and a second end of any one of the four capacitors is electrically connected to one of the accumulation lines.

6. The multi-bit analog multiplication and accumulation circuit system as claimed in claim 5, wherein a capacitance ratio of the four capacitors is 1:2:4:8.

7. The multi-bit analog multiplication and accumulation circuit system as claimed in claim 6, wherein the output node has the final multiplication and accumulation result.

8. The multi-bit analog multiplication and accumulation circuit system as claimed in claim 7, further comprising an analog to digital conversion module for converting the final multiplication and accumulation result into digital signal.

9. The multi-bit analog multiplication and accumulation circuit system as claimed in claim 8, wherein the analog to digital conversion module includes a digital to analog converter and a comparator, in which a first input end of the comparator is electrically connected with the digital to analog converter, and a second input end of the comparator is electrically connected with the output node.

10. The multi-bit analog multi-bit analog multiplication and accumulation circuit system as claimed in claim 9, wherein the digital to analog converter includes four switch capacitors, and each switch capacitor is electrically connected to one of three predetermined voltages through a switch, wherein the three predetermined voltages include a basic voltage, a basic voltage plus half a variable value, and a basic voltage plus a variable value.
